(19) United States
(12) Patent Application Publication
(10) Pub. No.: US 2026/0047135 A1
(43) Pub. Date: Feb. 12, 2026

(54) THIN FILM TRANSISTOR UNIT AND DISPLAY APPARATUS COMPRISING THE SAME

(71) Applicant: LG Display Co., Ltd., Seoul (KR)

(72) Inventors: GaWon Yang, Paju-si (KR); JuHeyuck Baeck, Paju-si (KR); Dohyung Lee, Paju-si (KR)

(73) Assignee: LG Display Co., Ltd., Seoul (KR)

(21) Appl. No.: 19/285,214

(22) Filed: Jul. 30, 2025

(30) Foreign Application Priority Data
Aug. 8, 2024 (KR) 10-2024-0106212

(51) Int. Cl. H10D 30/67; H10D 30/01

(52) U.S. Cl. CPC H10D 30/6734; H10D 30/0312

(57) ABSTRACT

A thin film transistor unit comprises: a base substrate; a first lower thin film transistor and a second lower thin film transistor disposed on the base substrate and connected in parallel to each other; a first upper thin film transistor and a second upper thin film transistor disposed on the first lower thin film transistor and the second lower thin film transistor and connected in parallel to each other, wherein the first upper thin film transistor comprises a first upper active layer and a first upper gate electrode disposed on a first upper active layer, the second upper thin film transistor comprises a second upper active layer and a second upper gate electrode disposed on the second upper active layer, and the first upper gate electrode and the second upper gate electrode are electrically connected, with a first upper drain electrode being interposed therebetween.

### CROSS-REFERENCE TO RELATED APPLICATION

This application claims the benefit of priority of the Korean Patent Application No. 10-2024-0106212, filed on Aug. 8, 2024, which is hereby incorporated by reference as if fully set forth herein.

### BACKGROUND

### Field of the Disclosure

The present disclosure relates to a thin film transistor unit and a display apparatus including the thin film transistor unit.

### Discussion of the Related Art

As the information society develops, the demand for display devices for displaying images is increasing in various forms, and recently, various display devices such as liquid crystal displays (LCDs), plasma display panels (PDPs), and organic light emitting diode display devices (OLEDs) are being utilized.

In general, a display device includes a driving circuit for driving a display panel. The driving circuit includes a gate driving circuit that sequentially applies scan signals to gate lines, and a data driving circuit that applies image information to pixels through data lines in response to scan signals of the gate driving circuit.

In the case of transistors in gate driving circuits, high bias voltage is applied to the gate electrode and drain electrode, so they may have characteristics that are vulnerable to heat generation.

Therefore, research has been continuously conducted recently to reduce the risk of heat generation in transistors in gate driving circuits.

### SUMMARY

An example embodiment of the present disclosure provides a thin film transistor unit in which the risk of heat generation is reduced while maintaining the total amount of current by distributing the current path.

An example embodiment of the present disclosure provides a thin film transistor unit in which the channel width is reduced while maintaining the channel length by disposing gate electrodes in parallel at the upper and lower ends, thereby securing a process margin.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with an aspect of the present disclosure, as embodied and broadly described herein, a thin film transistor unit includes a base substrate; a first lower thin film transistor and a second lower thin film transistor disposed on the base substrate and connected in parallel to each other; and a first upper thin film transistor and a second upper thin film transistor disposed on the first lower thin film transistor and the second lower thin film transistor and connected in parallel to each other, wherein the first upper thin film transistor comprises a first upper active layer and a first upper gate electrode disposed on the first upper active layer, the second upper thin film transistor comprises a second upper active layer and a second upper gate electrode disposed on the second upper active layer, the first upper gate electrode and the second upper gate electrode are electrically connected, with a first upper drain electrode being interposed therebetween, the first lower thin film transistor comprises a first lower gate electrode and a first lower active layer disposed on the first lower gate electrode, the second lower thin film transistor comprises a second lower gate electrode and a second lower active layer disposed on the second lower gate electrode, and the first lower gate electrode and the second lower gate electrode are electrically connected, with a first lower drain electrode being interposed therebetween.

The first upper gate electrode, the second upper gate electrode and the first upper drain electrode may be formed integrally, and the first lower gate electrode, the second lower gate electrode and the first lower drain electrode may be formed integrally.

The first upper active layer of the first upper thin film transistor and the second upper active layer of the second upper thin film transistor may be spaced apart from each other with a first connecting portion therebetween, and the first lower active layer of the first lower thin film transistor and the second lower active layer of the second lower thin film transistor may be spaced apart from each other with a second connecting portion therebetween.

The first upper active layer of the first upper thin film transistor and the second upper active layer of the second upper thin film transistor may be formed integrally with the first connecting portion, and the first lower active layer of the first lower thin film transistor and the second lower active layer of the second lower thin film transistor may be formed integrally with the second connecting portion.

In a plan view, the first upper gate electrode may overlap the first lower gate electrode, and the second upper gate electrode may overlap the second lower gate electrode.

In a plan view, the first upper active layer of the first upper thin film transistor may overlap the first lower active layer of the first lower thin film transistor, and the second upper active layer of the second upper thin film transistor may overlap the second lower active layer of the second lower thin film transistor.

The first connecting portion can be in contact with the first upper drain electrode, and the second connecting portion can be in contact with the first lower drain electrode.

The thin film transistor unit may further include a first buffer layer disposed between the first lower thin film transistor and the first upper thin film transistor, and disposed between the second lower thin film transistor and the second upper thin film transistor.

The first upper active layer of the first upper thin film transistor may be disposed between the first buffer layer and the first upper gate electrode, and the second upper active layer of the second upper thin film transistor may be disposed between the first buffer layer and the second upper gate electrode.

The first lower active layer of the first lower thin film transistor may be disposed between the first buffer layer and the first lower gate electrode, and the second lower active layer of the second lower thin film transistor may be disposed between the first buffer layer and the second lower gate electrode.

The thin film transistor unit may further include a second buffer layer disposed between the base substrate and the first buffer layer, wherein the first buffer layer may be formed by being patterned, and the second buffer layer may be disposed on the entire upper surface of the base substrate.

The thin film transistor unit may further include a first source electrode and a second source electrode, which are spaced apart from each other, wherein the first source electrode may be disposed spaced apart from the first upper drain electrode with the first upper active layer of the first upper thin film transistor interposed therebetween, and may be disposed spaced apart from the first lower drain electrode with the first lower active layer of the first lower thin film transistor interposed therebetween, and the second source electrode may be disposed spaced apart from the first upper drain electrode with the second upper active layer of the second upper thin film transistor interposed therebetween, and may be disposed spaced apart from the first lower drain electrode with the second lower active layer of the second lower thin film transistor interposed therebetween.

The first source electrode may contact the first upper active layer of the first upper thin film transistor and the first lower active layer of the first lower thin film transistor, respectively, and the second source electrode may contact the second upper active layer of the second upper thin film transistor and the second lower active layer of the second lower thin film transistor, respectively.

The first upper drain electrode and the first lower drain electrode can be connected through a first contact hole formed in the first buffer layer.

The first upper thin film transistor may further include a first gate insulating film disposed between the first upper active layer and the first upper gate electrode of the first upper thin film transistor, the second upper thin film transistor may further include a second gate insulating film disposed between the second upper active layer and the second upper gate electrode of the second upper thin film transistor, and the first gate insulating film and the second gate insulating film may be spaced apart from each other with a second contact hole therebetween, the first lower thin film transistor may further include a third gate insulating film disposed between the first lower active layer and the first lower gate electrode of the first lower thin film transistor, and the second lower thin film transistor may further include a fourth gate insulating film disposed between the second lower active layer and the second lower gate electrode of the second lower thin film transistor, and the third gate insulating film and the fourth gate insulating film may be spaced apart from each other with a third contact hole therebetween.

The first upper drain electrode may be formed within the second contact hole.

The second contact hole and the third contact hole may be disposed to overlap each other in a plan view.

The first lower active layer of the first lower thin film transistor may have a larger area than the first upper active layer of the first upper thin film transistor in a plan view. The second lower active layer of the second lower thin film transistor may have a larger area than the second upper active layer of the second upper thin film transistor in a plan view.

The first upper thin film transistor and the second upper thin film transistor may be disposed along a first direction, the first lower thin film transistor and the second lower thin film transistor may be disposed along the first direction, and when a direction intersecting the first direction is referred to as a second direction, wherein the thin film transistor unit may further include a third upper thin film transistor disposed along the second direction with the first upper thin film transistor, a fourth upper thin film transistor disposed along the second direction with the second upper thin film transistor, a third lower thin film transistor disposed along the second direction with the first lower thin film transistor, and a fourth lower thin film transistor disposed along the second direction with the second lower thin film transistor, the third upper thin film transistor and the fourth upper thin film transistor may be connected in parallel to each other, and the third lower thin film transistor and the fourth lower thin film transistor may be connected in parallel to each other.

The third upper thin film transistor may include a third upper active layer and a third upper gate electrode disposed on the third upper active layer, the fourth upper thin film transistor may include a fourth upper active layer and a fourth upper gate electrode disposed on the fourth upper active layer, the third upper gate electrode and the fourth upper gate electrode may be electrically connected, with a second upper drain electrode being interposed therebetween, the third lower thin film transistor may include a third lower gate electrode and a third lower active layer disposed on the third lower gate electrode, the fourth lower thin film transistor may include a fourth lower gate electrode and a fourth lower active layer disposed on the fourth lower gate electrode, and the third lower gate electrode and the fourth lower gate electrode may be electrically connected, with a second lower drain electrode being interposed therebetween.

The first upper drain electrode and the second upper drain electrode may be electrically connected with an upper bridge electrode therebetween, the first lower drain electrode and the second lower drain electrode may be electrically connected with a lower bridge electrode therebetween, and the upper bridge electrode and the lower bridge electrode may overlap in a plan view.

Another example embodiment of the present disclosure provides a display apparatus including any of the above examples of a thin film transistor unit.

It is to be understood that both the foregoing general description and the following detailed description are by way of example and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the present disclosure.

FIG. 1 is a plan view of a thin film transistor unit according to an example embodiment of the present disclosure.

FIG. 2 is a cross-sectional view taken along line I-I′ in FIG. 1.

FIG. 3 is a cross-sectional view taken along line II-II′ in FIG. 1.

FIG. 4 is a plan view of a thin film transistor unit according to another example embodiment of the present disclosure.

FIG. 5 is a cross-sectional view taken along line III-III′ in FIG. 4.

FIG. 6 is a cross-sectional view taken along line IV-IV′ in FIG. 4.

FIGS. 7A to 7I are process diagrams showing a manufacturing process of a thin film transistor unit according to an example embodiment of the present disclosure.

FIG. 8 is a schematic diagram of a display device according to an example embodiment of the present disclosure.

FIG. 9 is a schematic diagram of an example shift register.

FIG. 10 is a circuit diagram of an example embodiment of a stage provided in the shift register of FIG. 9.

FIG. 11 is a circuit diagram of a thin film transistor unit according to an example embodiment of the present disclosure.

### DETAILED DESCRIPTION

Advantages and features of the present disclosure and implementation methods thereof will be clarified through following example embodiments described with reference to the accompanying drawings. The present disclosure may, however, be embodied in different forms and should not be construed as limited to the embodiments set forth herein. Rather, these example embodiments are provided so that this disclosure will be thorough and complete and will fully convey the scope of the present disclosure to those skilled in the art. Further, the protected scope of the present disclosure may be defined by scopes of claims and their equivalents.

A shape, a size, a ratio, an angle and a number disclosed in the drawings for describing example embodiments of the present disclosure are merely an example, and thus the present disclosure is not limited to the illustrated details. Like reference numerals refer to like elements throughout the specification. In the following description, where the detailed description of the relevant known function or configuration may unnecessarily obscure a feature of the present disclosure, the detailed description may be omitted.

In a case where ‘comprise’, ‘have’ and ‘include’ described in the present disclosure are used, another portion may be added unless a more limiting term like ‘only˜’ is used. The terms of a singular form may include plural forms, and vice versa, unless referred to the contrary.

In construing an element, the element should be construed as including an error band although there is no explicit description.

In describing a position relationship, for example, where the position relationship is described as ‘upon˜’, ‘above˜’, ‘below˜’ and ‘next to˜’, one or more portions may be disposed between two other portions unless a more limiting term like ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It should be understood that these terms are intended to encompass different orientations of the device in addition to the orientation depicted in the drawings. For example, if the device illustrated in the figure is reversed, the device described to be arranged “below”, or “beneath” another device may be arranged “above” another device, and vice versa. Therefore, an exemplary term “below or beneath” may include “below or beneath” and “above” orientations. Likewise, an exemplary term “above” or “on” may include “above” and “below or beneath” orientations.

In describing a temporal relationship, for example, where the temporal order is described as “after,” “subsequent,” “next,” and “before,” a case which is not continuous may be included, unless a more limiting term like “just” or “direct” is used.

It should be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing example embodiments of the present disclosure, the same components can have the same sign as can be displayed on the other drawings.

In the example embodiments of the present disclosure, a source electrode and a drain electrode may be distinguished or separately identified for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area may be distinguished or separately refer to from a source electrode, and a drain area may be distinguished or separately refer to from a drain electrode, but embodiments of the present disclosure are not limited thereto. The source area may be the source electrode, and the drain area may be the drain electrode. In addition, the source area may be the drain electrode, and the drain area may be the source electrode.

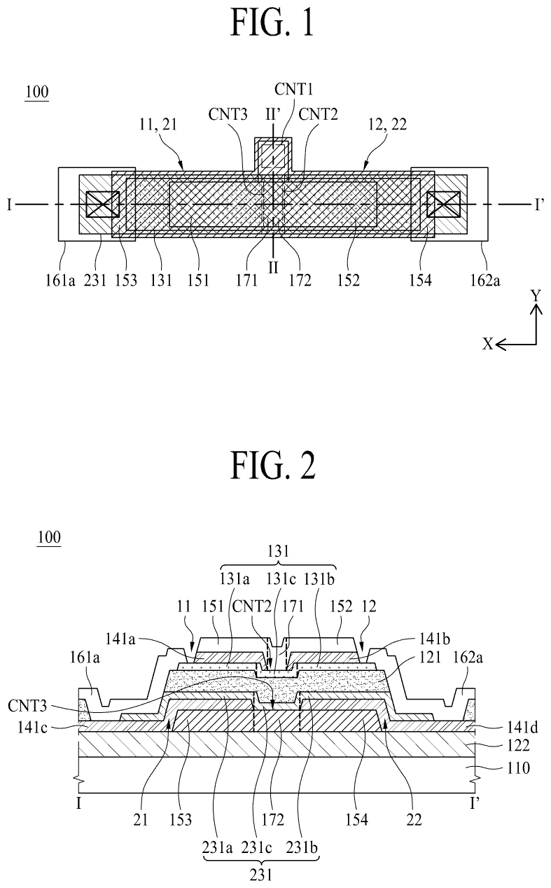

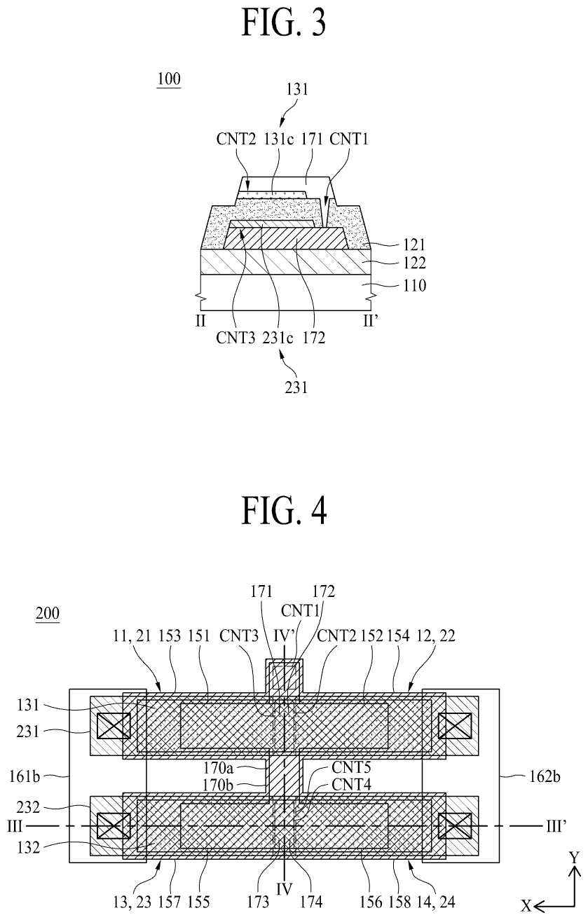

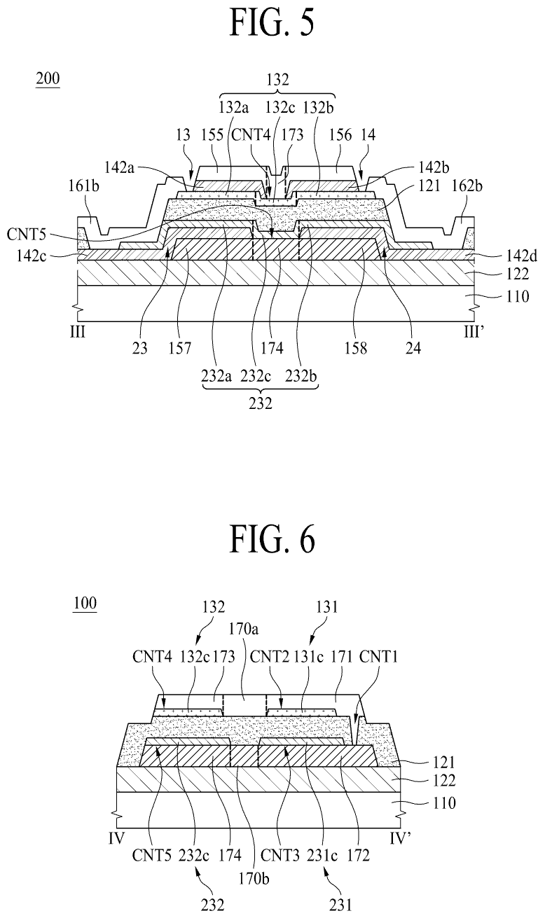

FIG. 1 is a plan view of a thin film transistor unit (100) according to an example embodiment of the present disclosure. FIG. 2 is a cross-sectional view taken along line I-I′ in FIG. 1. FIG. 3 is a cross-sectional view taken along line II-II′ in FIG. 1.

As shown in FIGS. 1, 2 and 3, a thin film transistor unit (100) according to an example embodiment of the present disclosure includes a first lower thin film transistor (21) and a second lower thin film transistor (22) connected in parallel with each other, and a first upper thin film transistor (11) and a second upper thin film transistor (12) connected in parallel with each other.

Specifically, as shown in FIGS. 1 to 3, a first lower thin film transistor (21) and a second lower thin film transistor (22) which are connected in parallel to each other and disposed on a base substrate (110), and a first upper thin film transistor (11) and a second upper thin film transistor (12) which are connected in parallel to each other and disposed on the first lower thin film transistor (21) and the second lower thin film transistor (22) are illustrated.

Below, components of a thin film transistor unit (100) according to an example embodiment of the present disclosure are described in detail.

The base substrate (110) may be made of glass or plastic. A transparent plastic having flexible properties, such as polyimide, may be used.

When polyimide is used as the base substrate (110), considering that a high-temperature deposition process is performed on the base substrate (110), a heat-resistant polyimide that can withstand high temperatures can be used. In this case, for forming a thin film transistor, processes such as deposition and etching can be performed while the polyimide substrate is disposed on a carrier substrate made of a highly durable material such as glass.

Although not shown in the drawing, a light-blocking layer (not shown) may be disposed on the base substrate (110).

A light-blocking layer (not shown) may be disposed between the base substrate (110) and the second buffer layer (122).

The light-blocking layer (not shown) can be made of a material having light-blocking properties. The light-blocking layer (not shown) can include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), and iron (Fe). According to an example embodiment of the present disclosure, the light-blocking layer (not shown) can have electrical conductivity.

As shown in FIGS. 2 and 3, a second buffer layer (122) may be disposed on a base substrate (110).

The second buffer layer (122) is formed on the base substrate (110) and may be formed of an inorganic material or an organic material. For example, it may include an insulating oxide such as silicon oxide (SiOx) or aluminum oxide (Al₂O₃).

The second buffer layer (122) protects the first active layer (131) and the second active layer (231) by blocking impurities such as moisture and oxygen flowing in from the base substrate (110) and serves to flatten the upper portion of the base substrate (110), and may be formed as a single layer or multiple layers.

If the second buffer layer (122) has multiple layers, each of the multiple layers can be formed of different materials.

As shown in FIGS. 1 to 3, a first upper thin film transistor (11), a second upper thin film transistor (12), a first lower thin film transistor (21), and a second lower thin film transistor are disposed in parallel.

The first upper thin film transistor (11) includes a first upper active layer (131a) and a first upper gate electrode (151) disposed on the first upper active layer (131a).

The second upper thin film transistor (12) includes a second upper active layer (131b) and a second upper gate electrode (152) disposed on the second upper active layer (131b).

The first lower thin film transistor (21) includes a first lower gate electrode (153) and a first lower active layer (231a) disposed on the first lower gate electrode (153).

The second lower thin film transistor (22) includes a second lower gate electrode (154) and a second lower active layer (231b) disposed on the second lower gate electrode (154).

As shown in FIGS. 1 and 2, the first upper gate electrode (151) and the second upper gate electrode (152) are spaced apart from each other by the first upper drain electrode (171). Specifically, the first upper gate electrode (151) and the second upper gate electrode (152) are electrically connected, with the first upper drain electrode (171) being interposed therebetween.

Specifically, the first upper gate electrode (151) and the second upper gate electrode (152) are formed integrally with the first upper drain electrode (171). More specifically, the first upper gate electrode (151), the second upper gate electrode (152), and the first upper drain electrode (171) are formed using the same material and through the same process.

According to an example embodiment of the present disclosure, the first upper gate electrode (151), the second upper gate electrode (152), and the first upper drain electrode (171) are defined by a region overlapping with a surface in contact with the first connecting portion (131c). Specifically, the region overlapping with the surface in contact with the first connecting portion (131c) may be referred to as the first upper drain electrode (171), a configuration disposed on one side while in contact with the first upper drain electrode (171) may be referred to as the first upper gate electrode (151), and a configuration disposed on the other side while in contact with the first upper drain electrode (171) may be referred to as the second upper gate electrode (152).

As shown in FIGS. 1 and 2, the first lower gate electrode (153) and the second lower gate electrode (154) are spaced apart from each other by the first lower drain electrode (172). Specifically, the first lower gate electrode (153) and the second lower gate electrode (154) are electrically connected, with the first lower drain electrode (172) being interposed therebetween.

Specifically, the first lower gate electrode (153) and the second lower gate electrode (154) are formed integrally with the first lower drain electrode (172). More specifically, the first lower gate electrode (153), the second lower gate electrode (154), and the first lower drain electrode (172) are formed using the same material and through the same process.

According to an example embodiment of the present disclosure, the first lower gate electrode (153), the second lower gate electrode (154), and the first lower drain electrode (172) are defined by a region overlapping a surface in contact with the second connecting portion (231c). Specifically, the region overlapping the surface in contact with the second connecting portion (231c) may be referred to as the first lower drain electrode (172), a configuration disposed on one side while in contact with the first lower drain electrode (172) may be referred to as the first lower gate electrode (153), and a configuration disposed on the other side while in contact with the first lower drain electrode (172) may be referred to as the second lower gate electrode (154).

According to an example embodiment of the present disclosure, the first upper active layer (131a) of the first upper thin film transistor (11) and the second upper active layer (131b) of the second upper thin film transistor (12) are spaced apart from each other with the first connecting portion (131c) therebetween.

Specifically, the first upper active layer (131a) of the first upper thin film transistor (11) and the second upper active layer (131b) of the second upper thin film transistor (12) are formed integrally with the first connecting portion (131c). More specifically, the first upper active layer (131a) of the first upper thin film transistor (11) and the second upper active layer (131b) of the second upper thin film transistor (12) are formed using the same material as the first connecting portion (131c) and by the same process.

According to an example embodiment of the present disclosure, the first upper active layer (131a) of the first upper thin film transistor (11), the second upper active layer (131b) of the second upper thin film transistor (12), and the first connecting portion (131c) may be combined to form a first active layer (131).

According to an example embodiment of the present disclosure, the first lower active layer (231a) of the first lower thin film transistor (21) and the second lower active layer (231b) of the second lower thin film transistor (22) are spaced apart from each other with the second connecting portion (231c) therebetween.

Specifically, the first lower active layer (231a) of the first lower thin film transistor (21) and the second lower active layer (231b) of the second lower thin film transistor (22) are formed integrally with the second connecting portion (231c). More specifically, the first lower active layer (231a) of the first lower thin film transistor (21) and the second lower active layer (231b) of the second lower thin film transistor (22) are formed using the same material as the second connecting portion (231c) and by the same process.

According to an example embodiment of the present disclosure, the first lower active layer (231a) of the first lower thin film transistor (21), the second lower active layer (231b) of the second lower thin film transistor (22) and the second connecting portion (231c) may be combined to form a second active layer (231).

According to an example embodiment of the present disclosure, the first connecting portion (131c) can be in contact with the first upper drain electrode (171), and the second connecting portion (231c) can be in contact with the first lower drain electrode (172).

According to an example embodiment of the present disclosure, the first upper active layer (131a) of the first upper thin film transistor (11) is electrically connected to the first upper drain electrode (171) through the first connecting portion (131c).

According to an example embodiment of the present disclosure, the second upper active layer (131b) of the second upper thin film transistor (12) is electrically connected to the first upper drain electrode (171) through the first connecting portion (131c).

According to an example embodiment of the present disclosure, the first lower active layer (231a) of the first lower thin film transistor (21) is electrically connected to the first lower drain electrode (172) through the second connecting portion (231c).

According to an example embodiment of the present disclosure, the second lower active layer (231b) of the second lower thin film transistor (22) is electrically connected to the first lower drain electrode (172) through the second connecting portion (231c).

As shown in FIGS. 1 to 3, the first upper gate electrode (151) may overlap the first lower gate electrode (153), and the second upper gate electrode (152) may overlap the second lower gate electrode (154) in a plan view.

Specifically, the entire area of the first upper gate electrode (151) may overlap with the first lower gate electrode (153), and the entire area of the second upper gate electrode (152) may overlap with the second lower gate electrode (154) in a plan view.

As shown in FIGS. 1 to 3, the first upper drain electrode (171) can overlap the first lower drain electrode (172) in a plan view.

FIGS. 1 to 3 illustrate a first upper drain electrode (171) overlapping a first lower drain electrode (172).

According to an example embodiment of the present disclosure, the first upper active layer (131a) of the first upper thin film transistor (11) may overlap the first lower active layer (231a) of the first lower thin film transistor (21) in a plan view.

Additionally, the second upper active layer (131b) of the second upper thin film transistor (12) may overlap the second lower active layer (231b) of the second lower thin film transistor (22) in a plan view.

In FIGS. 1 and 2, the first upper active layer (131a) of the first upper thin film transistor (11) overlaps the first lower active layer (231a) of the first lower thin film transistor (21) in a plan view, and the second upper active layer (131b) of the second upper thin film transistor (12) overlaps the second lower active layer (231b) of the second lower thin film transistor (22) in a plan view.

As shown in FIGS. 1 to 3, the first connecting portion (131c) and the second connecting portion (231c) can overlap in a plan view.

Specifically, the first upper drain electrode (171), the first connecting portion (131c), the second connecting portion (231c) and the first lower drain electrode (172) can overlap simultaneously in a plan view.

As shown in FIGS. 2 and 3, the thin film transistor unit (100) may further include a first buffer layer (121) disposed between the first upper thin film transistor (11) and the first lower thin film transistor (21), and disposed between the second upper thin film transistor (12) and the second lower thin film transistor (22). The second buffer layer (122) may be disposed between the base substrate (110) and the first buffer layer (121). The first buffer layer (121) may be formed by patterning, and the second buffer layer (122) may be disposed on the entire upper surface of the base substrate (110).

The first buffer layer (121) may be formed of an inorganic material or an organic material. For example, it may include an insulating oxide such as silicon oxide (SiOx) or aluminum oxide (Al₂O₃). The first buffer layer (121) may be formed of a single layer or multiple layers. In addition, the first buffer layer (121) may be formed of the same material as the second buffer layer (122), or may be formed of different materials.

According to an example embodiment of the present disclosure, the first upper active layer (131a) of the first upper thin film transistor (11) is disposed between the first buffer layer (121) and the first upper gate electrode (151), and the second upper active layer (131b) of the second upper thin film transistor (12) is disposed between the first buffer layer (121) and the second upper gate electrode (152).

According to an example embodiment of the present disclosure, the first lower active layer (231a) of the first lower thin film transistor (21) is disposed between the first buffer layer (121) and the first lower gate electrode (153), and the second lower active layer (231b) of the second lower thin film transistor (22) is disposed between the first buffer layer (121) and the second lower gate electrode (154).

FIG. 2 illustrates a first buffer layer (121) being disposed between the first active layer (131) and the second active layer (231).

According to an example embodiment of the present disclosure, the thin film transistor unit (100) includes a first source electrode (161a) and a second source electrode (162a) that are spaced apart from each other.

As shown in FIG. 2, the first source electrode (161a) is disposed spaced apart from the first upper drain electrode (171) with the first upper active layer (131a) of the first upper thin film transistor (11) interposed therebetween, and is disposed spaced apart from the first lower drain electrode (172) with the first lower active layer (231a) of the first lower thin film transistor (21) interposed therebetween.

Specifically, the first source electrode (161a) is electrically connected to the first upper drain electrode (171) through the first upper active layer (131a) and the first connecting portion (131c). In addition, the first source electrode (161a) is electrically connected to the first lower drain electrode (172) through the first lower active layer (231a) and the second connecting portion (231c).

As shown in FIG. 2, the second source electrode (162a) is disposed spaced apart from the first upper drain electrode (171) with the second upper active layer (131b) of the second upper thin film transistor (12) interposed therebetween, and is disposed spaced apart from the first lower drain electrode (172) with the second lower active layer (231b) of the second lower thin film transistor (22) interposed therebetween.

Specifically, the second source electrode (162a) is electrically connected to the first upper drain electrode (171) through the second upper active layer (131b) and the first connecting portion (131c). In addition, the second source electrode (162a) is electrically connected to the first lower drain electrode (172) through the second lower active layer (231b) and the second connecting portion (231c).

As shown in FIGS. 1 and 2, The first source electrode (161a) contacts the first upper active layer (131a) of the first upper thin film transistor (11) and the first lower active layer (231a) of the first lower thin film transistor (21), respectively.

Specifically, as shown in FIG. 2, the first source electrode (161a) can cover a portion of the side and upper surface of the first upper active layer (131a) of the first upper thin film transistor (11).

As shown in FIGS. 1 and 2, the second source electrode (162a) contacts the second upper active layer (131b) of the second upper thin film transistor (12) and the second lower active layer (231b) of the second lower thin film transistor (22), respectively.

Specifically, as shown in FIG. 2, the second source electrode (162a) can cover a portion of the side and upper surface of the second upper active layer (131b) of the second upper thin film transistor (12).

According to an example embodiment of the present disclosure, the first upper drain electrode (171) and the first lower drain electrode (172) can be connected through a first contact hole (CNT1) formed in the first buffer layer (121).

In FIG. 3, a first upper drain electrode (171) and a first lower drain electrode (172) are shown connected through a first contact hole (CNT1) formed in the first buffer layer (121).

According to an example embodiment of the present disclosure, the first upper thin film transistor (11) may further include a first gate insulating film (141a) disposed between the first upper active layer (131a) and the first upper gate electrode (151) of the first upper thin film transistor (11).

The first gate insulating film (141a) may include at least one of silicon oxide, silicon nitride, and metal oxide. The first gate insulating film (141a) may have a single film structure or a multilayer film structure.

The first gate insulating film (141a) can cover a part of the first upper active layer (131a) and expose a part of the first upper active layer (131a).

The area of the first upper active layer (131a) exposed by the first gate insulating film (141a) can be formed by selective conductorization.

According to an example embodiment of the present disclosure, the second upper thin film transistor (12) may further include a second gate insulating film (141b) disposed between the second upper active layer (131b) and the second upper gate electrode (152) of the second upper thin film transistor (12).

The second gate insulating film (141b) may be made of the same material as the first gate insulating film (141a), or may be made of different materials.

The area of the second upper active layer (131b) exposed by the second gate insulating film (141b) can be formed by selective conductorization.

As shown in FIG. 2, the first gate insulating film (141a) and the second gate insulating film (141b) can be separated from each other by the second contact hole (CNT2).

According to an example embodiment of the present disclosure, the second contact hole (CNT2) is formed by patterning to form the first gate insulating film (141a) and the second gate insulating film (141b). In addition, the second contact hole (CNT2) is formed to be surrounded by the first gate insulating film (141a) and the second gate insulating film (141b).

According to an example embodiment of the present disclosure, the first upper drain electrode (171) is formed within the second contact hole (CNT2).

FIG. 2 illustrates a first upper drain electrode (171) being formed within a second contact hole (CNT2).

According to an example embodiment of the present disclosure, the first lower thin film transistor (21) may further include a third gate insulating film (141c) disposed between the first lower active layer (231a) and the first lower gate electrode (153) of the first lower thin film transistor (21).

The third gate insulating film (141c) may be made of the same material as the first gate insulating film (141a) and the second gate insulating film (141b), or may be made of different materials.

According to an example embodiment of the present disclosure, the second lower thin film transistor (22) may further include a fourth gate insulating film (141d) disposed between the second lower active layer (231b) of the second lower thin film transistor (22) and the second lower gate electrode (154).

The fourth gate insulating film (141d) may be made of the same material as the first gate insulating film (141a), the second gate insulating film (141b), and the third gate insulating film (141c), or may be made of different materials.

As shown in FIG. 2, the third gate insulating film (141c) and the fourth gate insulating film (141d) can be separated from each other by the third contact hole (CNT3).

According to an example embodiment of the present disclosure, the third contact hole (CNT3) is formed by patterning to form a third gate insulating film (141c) and a fourth gate insulating film (141d). The third contact hole (CNT3) is formed to be surrounded by the third gate insulating film (141c) and the fourth gate insulating film (141d).

According to an example embodiment of the present disclosure, the second active layer (231) is formed within the third contact hole (CNT3). Specifically, the second connecting portion (231c) is formed within the third contact hole (CNT3).

According to an example embodiment of the present disclosure, the second contact hole (CNT2) and the third contact hole (CNT3) are disposed to overlap each other in a plan view.

Specifically, as shown in FIGS. 1 to 3, the second contact hole (CNT2) and the third contact hole (CNT3) are disposed to overlap each other.

According to an example embodiment of the present disclosure, the first upper active layer (131a), the second upper active layer (131b), and the first connecting portion (131c) of the first active layer (131) are partitioned based on both ends of the lower surface of the second contact hole (CNT2).

Additionally, the first lower active layer (231a), the second lower active layer (231b), and the second connecting portion (231c) of the second active layer (231) are partitioned based on both ends of the lower surface of the third contact hole (CNT3).

According to an example embodiment of the present disclosure, the first lower active layer (231a) of the first lower thin film transistor (21) may have a larger area than the first upper active layer (131a) of the first upper thin film transistor (11) in a plan view.

FIG. 1 illustrates that the first lower active layer (231a) of the first lower thin film transistor (21) has a larger area than the first upper active layer (131a) of the first upper thin film transistor (11).

In a plan view, the second lower active layer (231b) of the second lower thin film transistor (22) may have a larger area than the second upper active layer (131b) of the second upper thin film transistor (12).

According to an example embodiment of the present disclosure, the first lower gate electrode (153) may have a larger area than the first upper gate electrode (151) in a plan view. Additionally, the second lower gate electrode (154) may have a larger area than the second upper gate electrode (152) in a plan view.

According to an example embodiment of the present disclosure, the first upper thin film transistor (11) and the second upper thin film transistor (12) are disposed along the first direction (X). In addition, the first lower thin film transistor (21) and the second lower thin film transistor (22) are disposed along the first direction (X).

According to an example embodiment of the present disclosure, the first direction (X) means a direction that connects the first source electrode (161a) and the second source electrode (162a) at the shortest distance in a plan view.

Specifically, as shown in FIG. 1, the first upper gate electrode (151) and the second upper gate electrode (152) are disposed along the first direction (X), and the first lower gate electrode (153) and the second lower gate electrode (154) are disposed along the first direction (X).

More specifically, as shown in FIG. 1, the first upper active layer (131a) and the second upper active layer (131b) are disposed along the first direction (X), and the first lower active layer (231a) and the second lower active layer (231b) are disposed along the first direction (X).

As shown in FIG. 1, the first contact hole (CNT1) and the second contact hole (CNT2) are disposed along a second direction (Y) intersecting the first direction (X) in a plan view. In addition, the first contact hole (CNT1) and the third contact hole (CNT3) are disposed along the second direction (Y).

According to an example embodiment of the present disclosure, the second direction (Y) may be a direction perpendicular to the first direction (X).

According to an example embodiment of the present disclosure, the first upper gate electrode (151), the second upper gate electrode (152), the first lower gate electrode (153), and the second lower gate electrode (154) may each include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Specifically, the first upper gate electrode (151), the second upper gate electrode (152), the first lower gate electrode (153), and the second lower gate electrode (154) may have a multilayer film structure including at least two conductive films having different physical properties.

According to an example embodiment of the present disclosure, the first source electrode (161a) and the second source electrode (162a) may each include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Specifically, the first source electrode (161a) and the second source electrode (162a) may have a multilayer film structure including at least two conductive films having different physical properties.

According to an example embodiment of the present disclosure, the first upper drain electrode (171) is made of the same material as the first upper gate electrode (151) and the second upper gate electrode (152). In addition, the first lower drain electrode (172) is made of the same material as the first lower gate electrode (153) and the second lower gate electrode (154).

According to an example embodiment of the present disclosure, when the first upper thin film transistor (11) and the second upper thin film transistor (12) are commonly connected in parallel to the first upper drain electrode (171), and the first lower thin film transistor (21) and the second lower thin film transistor (22) are commonly connected in parallel to the first lower drain electrode (172), the current path can be distributed to the first sub-active layer (that is, the first upper active layer 131a, and the first lower active layer 231a) and the second sub-active layer (that is, the second upper active layer 131b, and the second lower active layer 231b).

Specifically, by disposing the first upper gate electrode (151) and the second upper gate electrode (152) at the top and disposing the first lower gate electrode (153) and the second lower gate electrode (154) at the bottom, the current path can be distributed to the first sub-active layer and the second sub-active layer.

Due to this, the channel width can be designed to be smaller than before in one current path, thereby reducing the amount of current and thus the amount of heat generated in the thin film transistor unit. As a result, the risk of heat generation in the thin film transistor unit can be reduced.

In general, when reducing the channel width to reduce the amount of heat generated in a thin film transistor unit, the heat generation may be reduced, but the total amount of current may be reduced.

However, the thin film transistor unit (100) according to an example embodiment of the present disclosure can maintain the total amount of current by distributing the current path to the first sub-active layer and the second sub-active layer instead of reducing the channel width.

In addition, by disposing the gate electrodes in parallel at the upper and lower ends, the channel width can be reduced while maintaining the channel length, thereby securing process margin.

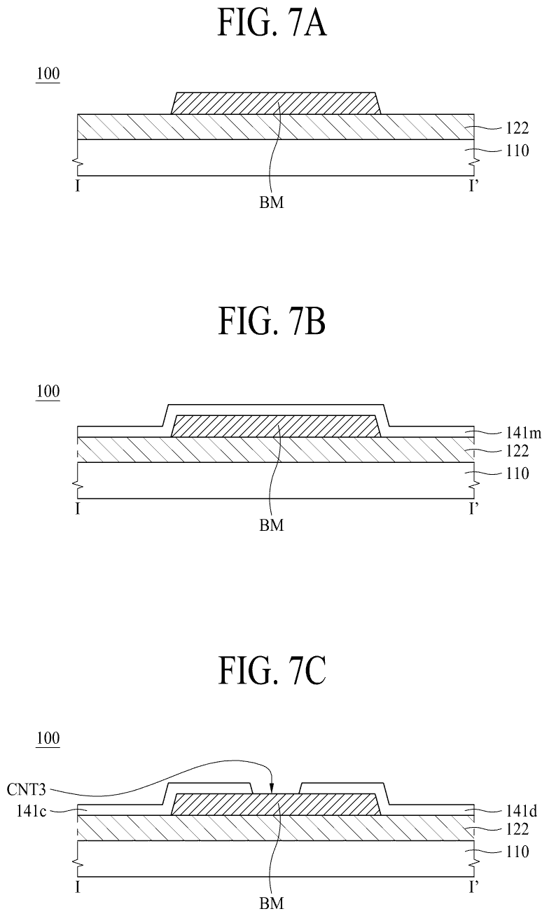

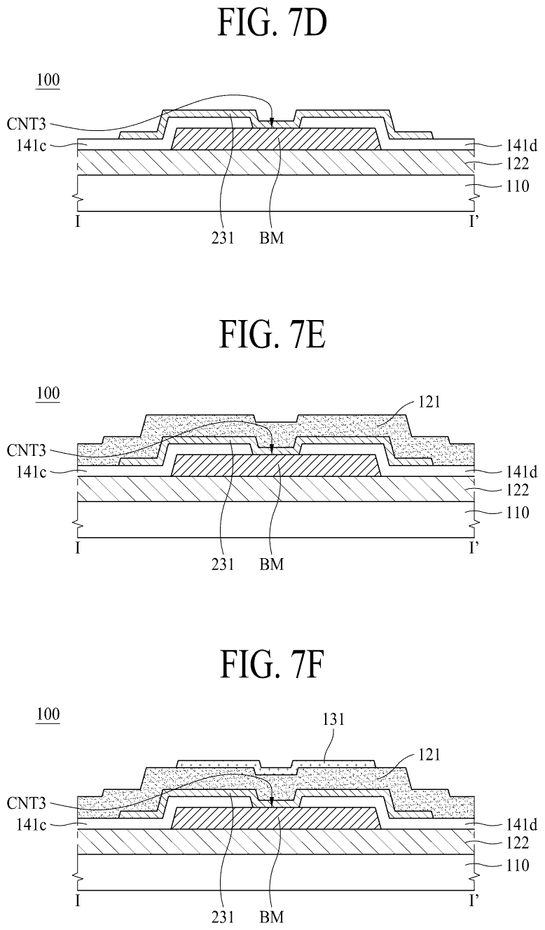

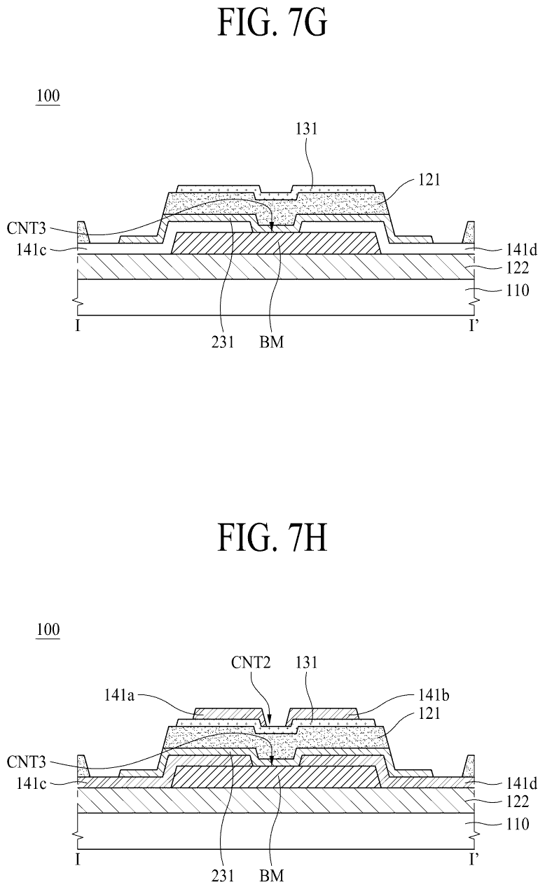

FIG. 4 is a plan view of a thin film transistor unit (200) according to another embodiment of the present disclosure. FIG. 5 is a cross-sectional view taken along line III-III′ in FIG. 4. FIG. 6 is a cross-sectional view taken along line IV-IV′ in FIG. 4.

According to an example embodiment of the present disclosure, the thin film transistor unit (200) further includes a third upper thin film transistor (13), a fourth upper thin film transistor (14), a third lower thin film transistor (23), and a fourth lower thin film transistor (24). Specifically, the thin film transistor unit (200) according to FIG. 4 may include eight thin film transistors (11, 12, 13, 14, 21, 22, 23, 24).

As shown in FIG. 4, the first upper thin film transistor (11) and the third upper thin film transistor (13) are disposed along the second direction (Y), the second upper thin film transistor (12) and the fourth upper thin film transistor (14) are disposed along the second direction (Y), the first lower thin film transistor (21) and the third lower thin film transistor (23) are disposed along the second direction (Y), and the second lower thin film transistor (22) and the fourth lower thin film transistor (24) are disposed along the second direction (Y).

Specifically, as shown in FIG. 4, the third upper thin film transistor (13), the fourth upper thin film transistor (14), the third lower thin film transistor (23), and the fourth lower thin film transistor (24) are disposed in different rows from the first upper thin film transistor (11), the second upper thin film transistor (12), the first lower thin film transistor (21), and the second lower thin film transistor (22) in a plan view.

According to an example embodiment of the present disclosure, the third upper thin film transistor (13) includes a third upper active layer (132a) and a third upper gate electrode (155) disposed on the third upper active layer (132a), and the fourth upper thin film transistor (14) includes a fourth upper active layer (132b) and a fourth upper gate electrode (156) disposed on the fourth upper active layer (132b).

According to an example embodiment of the present disclosure, the third upper gate electrode (155) and the fourth upper gate electrode (156) are spaced apart from each other by the second upper drain electrode (173). Specifically, the third upper gate electrode (155) and the fourth upper gate electrode (156) are electrically connected, with the second upper drain electrode (173) being interposed therebetween. Specifically, the third upper gate electrode (155) and the fourth upper gate electrode (156) are formed integrally with the second upper drain electrode (173).

The description of the first upper thin film transistor (11), the second upper thin film transistor (12), the first lower thin film transistor (21), and the second lower thin film transistor (22) illustrated in FIG. 4 repeats with the description of the first upper thin film transistor (11), the second upper thin film transistor (12), the first lower thin film transistor (21), and the second lower thin film transistor (22) illustrated in FIG. 1.

The description of the configuration of the third upper thin film transistor (13) and the fourth upper thin film transistor (14) illustrated in FIG. 5 repeats with the description of the configuration of the first upper thin film transistor (11) and the second upper thin film transistor (12) illustrated in FIG. 2.

According to an example embodiment of the present disclosure, the third lower thin film transistor (23) includes a third lower gate electrode (157) and a third lower active layer (232a) disposed on the third lower gate electrode (157), and the fourth lower thin film transistor (24) includes a fourth lower gate electrode (158) and a fourth lower active layer (232b) disposed on the fourth lower gate electrode (158).

According to an example embodiment of the present disclosure, the third lower gate electrode (157) and the fourth lower gate electrode (158) are spaced apart from each other by the second lower drain electrode (174). Specifically, the third lower gate electrode (157) and the fourth lower gate electrode (158) are electrically connected, with the second lower drain electrode (174) being interposed therebetween. Specifically, the third lower gate electrode (157) and the fourth lower gate electrode (158) are formed integrally with the second lower drain electrode (174).

The description of the configuration of the third lower thin film transistor (23) and the fourth lower thin film transistor (24) illustrated in FIG. 5 repeats with the description of the configuration of the first lower thin film transistor (21) and the second lower thin film transistor (22) illustrated in FIG. 2.

The description of the fifth gate insulating film (142a), the sixth gate insulating film (142b), the seventh gate insulating film (142c), and the eighth gate insulating film (142d) illustrated in FIG. 5 repeats with the description of the first gate insulating film (141a), the second gate insulating film (141b), the third gate insulating film (141c), and the fourth gate insulating film (141d) illustrated in FIG. 2.

The fifth gate insulating film (142a) and the sixth gate insulating film (142b) illustrated in FIG. 5 are separated from each other by the fourth contact hole (CNT4). The description of the fourth contact hole (CNT4) is omitted because it repeats with the description of the second contact hole (CNT2) illustrated in FIG. 2.

The seventh gate insulating film (142c) and the eighth gate insulating film (142d) illustrated in FIG. 5 are separated from each other by the fifth contact hole (CNT5). The description of the fifth contact hole (CNT5) is omitted because it repeats with the description of the third contact hole (CNT3) illustrated in FIG. 2.

As shown in FIG. 4, the first contact hole (CNT1), the second contact hole (CNT2), the third contact hole (CNT3), the fourth contact hole (CNT4), and the fifth contact hole (CNT5) are disposed along the second direction (Y) in a plan view.

As shown in FIGS. 4 and 5, the first source electrode (161b) is disposed spaced apart from the first upper drain electrode (171) with the first upper active layer (131a) of the first upper thin film transistor (11) interposed therebetween, is disposed spaced apart from the first lower drain electrode (172) with the first lower active layer (231a) of the first lower thin film transistor (21) interposed therebetween, is disposed spaced apart from the second upper drain electrode (173) with the third upper active layer (132a) of the third upper thin film transistor (13) interposed therebetween, and is disposed spaced apart from the second lower drain electrode (174) with the third lower active layer (232a) of the third lower thin film transistor (23) interposed therebetween.

Specifically, the first source electrode (161b) is electrically connected to the first upper drain electrode (171) via the first upper active layer (131a) and the first connection portion (131c), and the first source electrode (161b) is electrically connected to the first lower drain electrode (172) via the first lower active layer (231a) and the second connection portion (231c). In addition, the first source electrode (161b) is electrically connected to the second upper drain electrode (173) via the third upper active layer (132a) and the third connection portion (132c), and the first source electrode (161b) is electrically connected to the second lower drain electrode (174) via the third lower active layer (232a) and the fourth connection portion (232c).

According to an example embodiment of the present disclosure, the third upper active layer (132a) of the third upper thin film transistor (13), the fourth upper active layer (132b) of the fourth upper thin film transistor (14), and the third connecting portion (132c) may be combined to form a third active layer (132).

According to an example embodiment of the present disclosure, the third lower active layer (232a) of the third lower thin film transistor (23), the fourth lower active layer (232b) of the fourth lower thin film transistor (24), and the fourth connecting portion (232c) may be combined to form a fourth active layer (232).

As shown in FIGS. 4 and 5, the second source electrode (162b) is disposed spaced apart from the first upper drain electrode (171) with the second upper active layer (131b) of the second upper thin film transistor (12) interposed therebetween, is disposed spaced apart from the first lower drain electrode (172) with the second lower active layer (231b) of the second lower thin film transistor (22) interposed therebetween, is disposed spaced apart from the second upper drain electrode (173) with the fourth upper active layer (132b) of the fourth upper thin film transistor (14) interposed therebetween, and is disposed spaced apart from the second lower drain electrode (174) with the fourth lower active layer (232b) of the fourth lower thin film transistor (24) interposed therebetween.

Specifically, the second source electrode (162b) is electrically connected to the first upper drain electrode (171) through the second upper active layer (131b) and the first connection portion (131c), and the second source electrode (162b) is electrically connected to the first lower drain electrode (172) through the second lower active layer (231b) and the second connection portion (231c). In addition, the second source electrode (162b) is electrically connected to the second upper drain electrode (173) through the fourth upper active layer (132b) and the third connection portion (132c), and the second source electrode (162b) is electrically connected to the second lower drain electrode (174) through the fourth lower active layer (232b) and the fourth connection portion (232c).

According to an example embodiment of the present disclosure, the first upper drain electrode (171) and the second upper drain electrode (173) are disposed to be spaced apart from each other by the upper bridge electrode (170a). In addition, the first lower drain electrode (172) and the second lower drain electrode (174) are disposed to be spaced apart from each other by the lower bridge electrode (170b). Specifically, the first upper drain electrode (171) and the second upper drain electrode (173) are electrically connected to each other with the upper bridge electrode (170a) therebetween, and the first lower drain electrode (172) and the second lower drain electrode (174) are electrically connected to each other with the lower bridge electrode (170b) therebetween.

As shown in FIGS. 4 and 6, the first upper drain electrode (171) and the second upper drain electrode (173) are formed integrally with the upper bridge electrode (170a). Specifically, the first upper drain electrode (171) and the second upper drain electrode (173) can be formed using the same material as the upper bridge electrode (170a) through the same process.

In addition, the first lower drain electrode (172) and the second lower drain electrode (174) are formed integrally with the lower bridge electrode (170b). Specifically, the first lower drain electrode (172) and the second lower drain electrode (174) can be formed using the same material as the lower bridge electrode (170b) through the same process.

According to an example embodiment of the present disclosure, the upper bridge electrode (170a) and the lower bridge electrode (170b) are disposed to overlap each other in a plan view.

As shown in FIGS. 4 and 6, the first upper drain electrode (171) and the second upper drain electrode (173) can be electrically connected to the first lower drain electrode (172) and the second lower drain electrode (174) through the first contact hole (CNT1).

As with the thin film transistor unit (100) illustrated in FIGS. 1 to 3, if the first upper thin film transistor (11) and the second upper thin film transistor (12) of the thin film transistor unit (200) illustrated in FIGS. 4 to 6 are commonly connected in parallel to the first upper drain electrode (171), the third upper thin film transistor (13) and the fourth upper thin film transistor (14) are commonly connected in parallel to the second upper drain electrode (173), the first lower thin film transistor (21) and the second lower thin film transistor (22) are commonly connected in parallel to the first lower drain electrode (172), and the third lower thin film transistor (23) and the fourth lower thin film transistor (24) are commonly connected in parallel to the second lower drain electrode (174), the current path can be dispersed to the first sub-active layer (that is, the first upper active layer 131a, the third upper active layer 132a, the first lower active layer 231a, and the third lower active layer 232a) and the second sub-active layer (that is, the second upper active layer 131b, the fourth upper active layer 132b, the second lower active layer 231b, and the fourth lower active layer 232b).

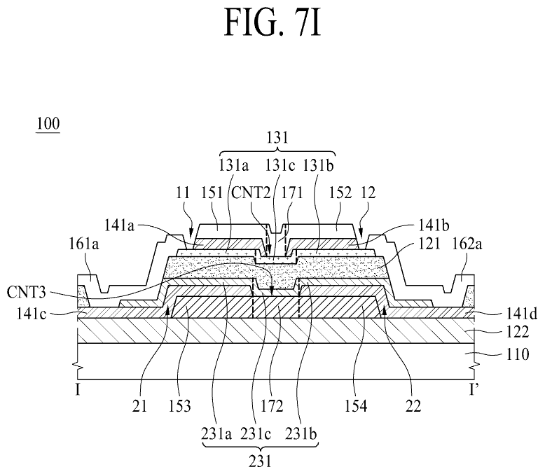

FIGS. 7A to 7I are process diagrams showing a manufacturing process of a thin film transistor unit (100) according to an example embodiment of the present disclosure.

The cross-sectional views of the thin film transistor unit (100) illustrated in FIGS. 7A to 7I correspond to the cross-sectional views of the thin film transistor unit (100) illustrated in FIG. 2.

As shown in FIG. 7A, after forming a base substrate (110) and a second buffer layer (122) in sequence, a lower metal layer (BM) can be formed on the second buffer layer (122) and then patterned. The lower metal layer (BM) corresponds to the first lower gate electrode (153), the second lower gate electrode (154) and the first lower drain electrode (172).

According to an example embodiment of the present disclosure, the lower metal layer (BM) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti).

As shown in FIG. 7B, a first gate insulating material layer (141m) can be formed on the lower metal layer (BM) and the second buffer layer (122).

According to an example embodiment of the present disclosure, the first gate insulating material layer (141m) may include at least one of silicon oxide, silicon nitride, and metal-based oxide.

As shown in FIG. 7C, a third contact hole (CNT3) exposing the lower metal layer (BM) can be formed by patterning the first gate insulating material layer (141m).

The third contact hole (CNT3) illustrated in FIG. 7C corresponds to the third contact hole (CNT3) illustrated in FIG. 2.

Specifically, the first gate insulating material layer (141m) can be patterned to form a third gate insulating film (141c) and a fourth gate insulating film (141d). The third gate insulating film (141c) and the fourth gate insulating film (141d) are disposed to be spaced apart from each other by a third contact hole (CNT3).

As shown in FIG. 7D, a second active layer (231) can be formed on the lower metal layer (BM), the third gate insulating film (141c), and the fourth gate insulating film (141d). As shown in FIG. 7D, the second active layer (231) is formed by patterning.

As shown in FIG. 7E, a first buffer layer (121) can be formed on the third gate insulating film (141c), the fourth gate insulating film (141d), and the second active layer (231).

According to an example embodiment of the present disclosure, the first buffer layer (121) is disposed on the entire upper surface of the third gate insulating film (141c), the fourth gate insulating film (141d) and the second active layer (231).

As shown in FIG. 7F, a first active layer (131) can be formed on a first buffer layer (121). The first active layer (131) is formed by patterning.

As shown in FIG. 7G, a hole can be formed by patterning the first buffer layer (121).

As shown in FIG. 7G, a portion of the second active layer (231), a portion of the third gate insulating film (141c) and a portion the fourth gate insulating film (141d) can be exposed by patterning the first buffer layer (121).

As shown in FIG. 7H, a first gate insulating film (141a) and a second gate insulating film (141b) can be formed on the first active layer (131). The first gate insulating film (141a) and the second gate insulating film (141b) are formed by patterning and are spaced apart from each other by a second contact hole (CNT2).

As shown in FIG. 7I, a first upper gate electrode (151), a second upper gate electrode (152), and a first upper drain electrode (171) can be formed on a first gate insulating film (141a) and a second gate insulating film (141b). In addition, a first source electrode (161a) and a second source electrode (162a) can be formed in a hole formed by patterning a first buffer layer (121).

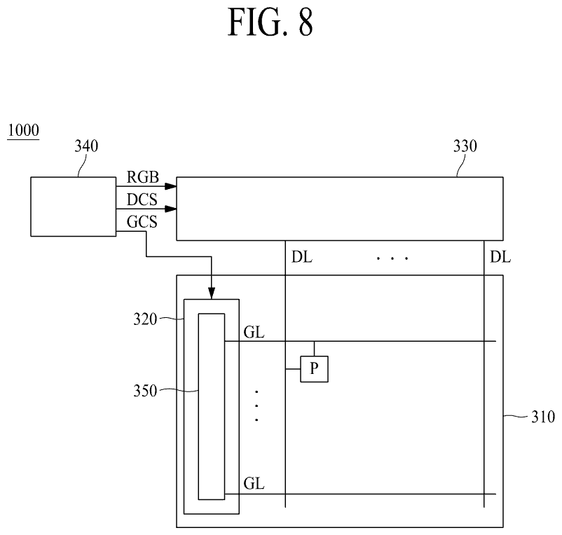

FIG. 8 is a schematic diagram of a display device (1000) according to another example embodiment of the present disclosure.

A display device (1000) according to another example embodiment of the present disclosure may include a display panel (310), a gate driver (320), a data driver (330), and a control unit (340), as illustrated in FIG. 8.

The display panel (310) includes gate lines (GL) and data lines (DL), and pixels (P) are disposed at intersections of the gate lines (GL) and data lines (DL). An image is displayed by driving the pixels (P). The gate lines (GL), data lines (DL), and pixels (P) may be disposed on a base substrate (110).

The control unit (340) controls the gate driver (320) and the data driver (330).

The control unit (340) outputs a gate control signal (GCS) for controlling the gate driver (320) and a data control signal (DCS) for controlling the data driver (330) using a signal supplied from an external system (not shown). In addition, the control unit (340) samples input image data input from an external system, rearranges it, and supplies rearranged digital image data (RGB) to the data driver (330).

Gate Control signal (GCS) includes a gate start pulse (GSP), a gate shift clock (GSC), a gate output enable signal (GOE), a start signal (Vst), and a gate clock (GCLK). In addition, the gate control signal (GCS) may include control signals for controlling the shift register.

Data control signals (DCS) include source start pulse (SSP), source shift clock signal (SSC), source output enable signal (SOE), and polarity control signal (POL).

The data driver (330) supplies data voltage to the data lines (DL) of the display panel (310). Specifically, the data driver (330) converts digital image data (RGB) input from the control unit (340) into analog data voltage and supplies the data voltage to data lines (DL).

According to an example embodiment of the present disclosure, the gate driver (320) may be mounted on the display panel (310). In this way, a structure in which the gate driver (320) is directly mounted on the display panel (310) is called a gate in panel (GIP) structure. Specifically, in the gate in panel (GIP) structure, the gate driver (320) may be disposed on the base substrate (110).

A display device (1000) according to an example embodiment of the present disclosure may include the thin film transistor unit (100, 200) described above. According to an example embodiment of the present disclosure, a gate driver (320) may include the thin film transistor unit (100, 200) described above.

The gate driver (320) may include a shift register (350).

Shift register (350) sequentially supplies gate pulses to gate lines (GL) for one frame using a start signal and gate clock transmitted from the control unit (340). Here, one frame refers to a period during which one image is output through the display panel (310). The gate pulse has a turn-on voltage capable of turning on a switching element (thin film transistor) disposed in a pixel (P).

In addition, the shift register (350) supplies a gate off signal capable of turning off the switching element to the gate line (GL) during the remaining period during which the gate pulse is not supplied during one frame. Hereinafter, the gate pulse and the gate off signal are collectively referred to as a scan signal (SS).

The shift register (350) may include the thin film transistor unit (100, 200) described above.

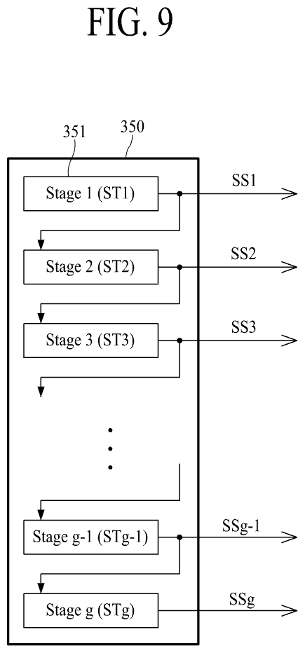

FIG. 9 is a schematic diagram of an example shift register (350).

As shown in FIG. 9, the shift register (350) may include g stages (351) (ST1 to STg).

The shift register (350) transmits one scan signal (SS) to pixels (P) connected to one gate line (GL) through one gate line (GL). Each of the stages (351) can be connected to one gate line (GL). When g gate lines (GL) are formed in the display panel (310), the shift register (350) can include g stages (351) (ST1 to STg) and generate g scan signals (SS1 to SSg).

In general, each stage (351) outputs a gate pulse once during one frame, and the gate pulses are sequentially output from each stage (351).

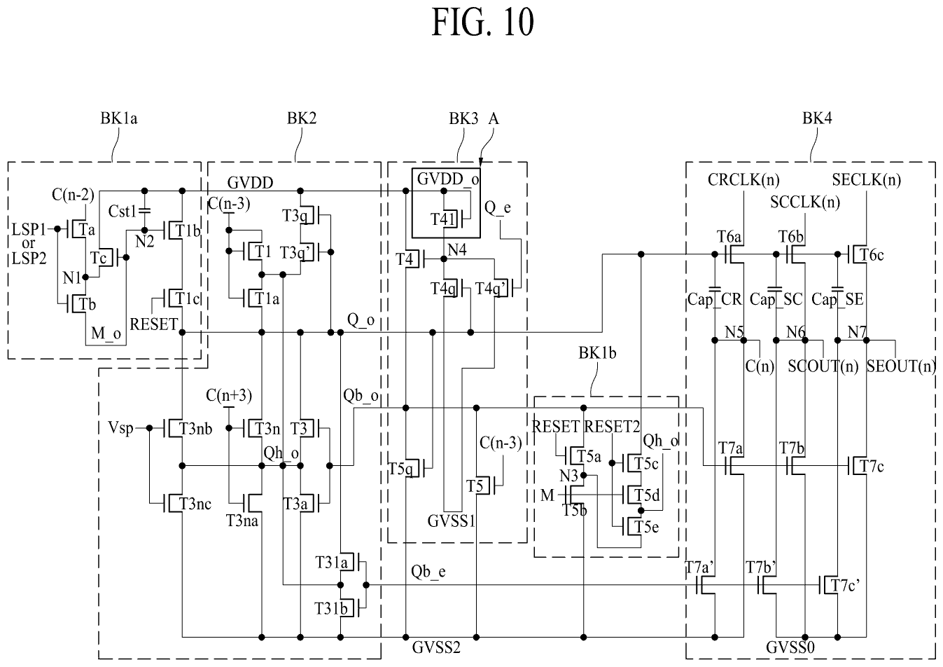

FIG. 10 is a circuit diagram of an example embodiment of a stage (351) provided in the shift register (350) of FIG. 9.

As shown in FIG. 10, a stage (ST) according to an example embodiment of the present disclosure includes a M_o node, a Q_o node, a Q_e node, a Qb_o node, a Qb_e node, and a Qh_o node.

As shown in FIG. 10, the stage (ST) includes a first sensing control block (BKla), a second sensing control block (BK1b), an input block (BK2), an inverter block (BK3), and an output block (BK4).

The first sensing control block (BKla) applies a carry signal C(n−2) to the node M_o according to the line sampling signals (LSP1, LSP2) to activate the potential of the node M_o to the high-potential power supply voltage GVDD, and activates the potential of the node Q_o to the high-potential power supply voltage GVDD according to the activation potential of the node M_o and the global reset signal (RESET).

For this purpose, the first sensing control block (BKla) includes a plurality of transistors (Ta, Tb, Tc, Tlb, Tlc) and a capacitor (Cst1).

Transistor Ta includes a gate electrode to which line sampling signals (LSP1, LSP2) are applied, a drain electrode to which a carry signal C(n−2) is applied, and a source electrode connected to node N1. Transistor Tb includes a gate electrode to which line sampling signals (LSP1, LSP2) are applied, a drain electrode connected to node N1, and a source electrode connected to node M_o. Transistor Tc includes a gate electrode connected to node N2, a drain electrode to which a high-potential power supply voltage GVDD is applied, and a source electrode connected to node N1. Transistor T1b includes a gate electrode connected to node N2, a drain electrode to which a high-potential power supply voltage GVDD is applied, and a source electrode connected to the drain electrode of transistor T1c. Capacitor Cst1 is connected between an input terminal of the high-potential power supply voltage GVDD and node N2 to maintain an activation potential of node M_o. Transistor T1c includes a gate electrode to which a global reset signal (RESET) is applied, a drain electrode connected to the source electrode of transistor T1b, and a source electrode connected to node Q_o.

The second sensing control block (BK1b) deactivates the potential of node Qb_o to the low potential power supply voltage GVSS2 according to the global reset signal (RESET) and the potential of node M.

To this end, the second sensing control block (BK1b) includes a plurality of transistors (T5a, T5b, T5c, T5d, T5e). The transistor T5a includes a gate electrode to which a global reset signal (RESET) is applied, a drain electrode connected to a node Qb_o, and a source electrode connected to a node N3. The transistor T5b includes a gate electrode connected to a node M, a drain electrode connected to a node N3, and a source electrode to which a low-potential power supply voltage GVSS2 is applied. The transistor T5c includes a gate electrode to which a second global reset signal (RESET2) is applied, a drain electrode connected to a node Q_o, and a source electrode connected to the drain electrode of the transistor T5d. The transistor T5d includes a gate electrode to which a second global reset signal (RESET2) is applied, a drain electrode connected to the source electrode of the transistor T5c, and a source electrode connected to the node Qh_o. Transistor T5e includes a gate electrode to which a second global reset signal (RESET2) is applied, a drain electrode connected to node Qh_o, and a source electrode connected to node N3.

The input block (BK2) applies a carry signal C(n−3) to the node Q_o to activate the potential of the node Qh_o to the high-potential power supply voltage GVDD. The second sensing control block (BK1b) deactivates the potential of the node Q_o to the low-potential power supply voltage GVSS2 according to the carry signal C (n+3). The second sensing control block (BK1b) deactivates the potential of the node Q_o to the low-potential power supply voltage GVSS2 according to the potential of the node Qb_o or Qb_e. The second sensing control block (BK1b) deactivates the potential of the node Q_o to the low-potential power supply voltage GVSS2 according to the global start pulse (Vsp).

For this purpose, the input block (BK2) includes a plurality of transistors (T1, T1a, T3q, T3q′, T3n, T3na, T3, T3a, T31a, T31b, T3nb, T3nc). The transistor T1 includes a gate electrode and a drain electrode to which a carry signal C(n−3) is applied, and a source electrode connected to a node Qh_o. The transistor T1a includes a gate electrode to which a carry signal C(n−3) is applied, a drain electrode connected to the node Qh_o, and a source electrode connected to the node Q_o. The transistor T3q includes a gate electrode connected to the node Q_o, a drain electrode to which a high-potential power supply voltage GVDD is applied, and a source electrode connected to the drain electrode of the transistor T3q′. The transistor T3q′ includes a gate electrode connected to the node Q_o, a drain electrode connected to the source electrode of the transistor T3q, and a source electrode connected to the node Qh_o. The transistor T3n includes a gate electrode to which a carry signal C (n+3) is applied, a drain electrode connected to a node Q_o, and a source electrode connected to a node Qh_o. The transistor T3na includes a gate electrode to which a carry signal C (n+3) is applied, a drain electrode connected to a node Qh_o, and a source electrode to which a low-potential power supply voltage GVSS2 is applied. The transistor T3 includes a gate electrode connected to a node Qb_o, a drain electrode connected to a node Q_o, and a source electrode connected to a node Qh_o. The transistor T3a includes a gate electrode connected to a node Qb_o, a drain electrode connected to a node Qh_o, and a source electrode to which a low-potential power supply voltage GVSS2 is applied. The transistor T31a includes a gate electrode connected to a node Qb_e, a drain electrode connected to a node Q_o, and a source electrode connected to a node Qh_o. The transistor T31b includes a gate electrode connected to a node Qb_e, a drain electrode connected to a node Qh_o, and a source electrode to which a low-potential power supply voltage GVSS2 is applied. The transistor T3nb includes a gate electrode to which a global start pulse (Vsp) is applied, a drain electrode connected to a node Q_o, and a source electrode connected to the node Qh_o. The transistor T3nc includes a gate electrode to which a global start pulse (Vsp) is applied, a drain electrode connected to a node Qh_o, and a source electrode to which a low-potential power supply voltage GVSS2 is applied.

The inverter block (BK3) deactivates the potential of node Qb_o to the low-potential power supply voltage GVSS2 according to the carry signal C(n−3). The inverter block (BK3) deactivates the potential of node Qb_o to the low-potential power supply voltage GVSS2 according to the activation potential of node Q_o. The inverter block (BK3) applies the power supply voltage GVDD_o to the node N4 to activate the potential of node Qb_o to the power supply voltage GVDDo. The inverter block (BK3) deactivates the potential of the node N4 to the low-potential power supply voltage GVSS2 according to the activation potential of node Q_e.

For this purpose, the inverter block (BK3) includes a plurality of transistors (T4, T41, T4q, T4q′, T5, T5q). The transistor T4 includes a gate electrode connected to a node N4, a drain electrode to which a power supply voltage GVDD_o is applied, and a source electrode connected to a node Qb_o. The transistor T41 includes a gate electrode and a drain electrode to which a power supply voltage GVDD_o is applied, and a source electrode connected to the node N4. The transistor T4q includes a gate electrode connected to a node Q_o, a drain electrode connected to a node N4, and a source electrode to which a low-potential power supply voltage GVSS1 is applied. The transistor T4q′ includes a gate electrode connected to a node Q_e, a drain electrode connected to a node N4, and a source electrode to which a low-potential power supply voltage GVSS1 is applied. Transistor T5 includes a gate electrode to which a carry signal C(n−3) is applied, a drain electrode connected to node Qb_o, and a source electrode to which a low-potential power supply voltage GVSS2 is applied. Transistor T5q includes a gate electrode connected to node Q_o, a drain electrode connected to node Qb_o, and a source electrode to which a low-potential power supply voltage GVSS2 is applied.

According to an example embodiment of the present disclosure, the transistor T41 may include a thin film transistor unit (100, 200) according to an example embodiment of the present disclosure.

The output block (BK4) outputs a carry shift clock CRCLK(n) as a carry signal C (n) when the potential of the node Q_o is boosted from a first voltage level to a second voltage level, and outputs a low-potential power supply voltage GVSS2 as a carry signal C (n) when the potential of the node Qb_o is activated to the first voltage level or when the potential of the node Qb_e is activated to the first voltage level. The output block (BK4) outputs a scan shift clock SCCLK(n) as a gate pulse SCOUT(n) for image display when the potential of the node Q_o is boosted from a first voltage level to a second voltage level, and outputs a low-potential power supply voltage GVSS0 as a gate pulse SCOUT(n) for image display when the potential of the node Qb_o is activated to the first voltage level or when the potential of the node Qb_e is activated to the first voltage level. The output block (BK4) outputs the sense shift clock SECLK(n) as the sense signal SEOUT(n) when the potential of node Q_o is boosted from a first voltage level to a second voltage level, and outputs the low-voltage power supply voltage GVSS0 as the sense signal SEOUT(n) when the potential of node Qb_o is activated to the first voltage level or when the voltage of node Qb_e is activated to the first voltage level.

For this purpose, the output block (BK4) includes a plurality of pull-up transistors (T6a, T6b, T6c), a plurality of pull-down transistors (T7a, T7a′, T7b, T7b′, T7c, T7c′), and a plurality of capacitors (Cap_CR, Cap_SC, Cap_SE). The pull-up transistor T6a includes a gate electrode connected to the node Q_o, a drain electrode to which a carry shift clock CRCLK(n) is applied, and a source electrode connected to the node N5. The capacitor Cap_CR is connected between the node Q_o and the node N5. The pull-up transistor T6b includes a gate electrode connected to the node Q_o, a drain electrode to which a scan shift clock SCCLK(n) is applied, and a source electrode connected to the node N6. The capacitor Cap_SC is connected between the node Q_o and the node N6. The pull-up transistor T6c includes a gate electrode connected to the node Q_o, a drain electrode to which a sense shift clock SECLK(n) is applied, and a source electrode connected to the node N7. A capacitor Cap_SE is connected between the node Q_o and the node N7. The pull-down transistor T7a includes a gate electrode connected to the node Qb_o, a drain electrode connected to the node N5, and a source electrode to which a low-potential power supply voltage GVSS2 is applied. The pull-down transistor Ta′ includes a gate electrode connected to the node Qb_e, a drain electrode connected to the node N5, and a source electrode to which a low-potential power supply voltage GVSS2 is applied. The pull-down transistor T7b includes a gate electrode connected to the node Qb_o, a drain electrode connected to the node N6, and a source electrode to which a low-potential power supply voltage GVSS0 is applied. The pull-down transistor T7b′ includes a gate electrode connected to the node Qb_e, a drain electrode connected to the node N6, and a source electrode to which a low-potential power supply voltage GVSS0 is applied. The pull-down transistor T7c includes a gate electrode connected to the node Qb_o, a drain electrode connected to the node N7, and a source electrode to which the low-potential power supply voltage GVSS0 is applied. The pull-down transistor T7c′ includes a gate electrode connected to the node Qb_e, a drain electrode connected to the node N7, and a source electrode to which the low-potential power supply voltage GVSS0 is applied.

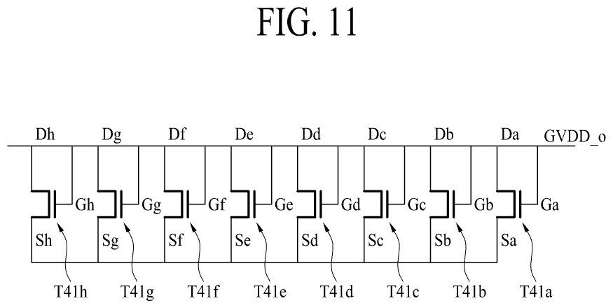

FIG. 11 is a circuit diagram of a thin film transistor unit (200) according to an example embodiment of the present disclosure. Specifically, FIG. 11 may be a drawing showing the appearance of area A illustrated in FIG. 10.

FIG. 11 illustrates eight transistors (T41a, T41b, T41c, T41d, T41e, T41f, T41g, T41h) disposed in parallel.

Each of the eight transistors (T41a, T41b, T41c, T41d, T41e, T41f, T41g, T41h) includes a gate electrode (Ga, Gb, Gc, Gd, Ge, Gf, Gg, Gh), a source electrode (Sa, Sb, Sc, Sd, Se, Sf, Sg, Sh), and a drain electrode (Da, Db, Dc, Dd, De, Df, Dg, Dh).

An example embodiment of the present disclosure is not limited thereto, and the thin film transistor unit may include four thin film transistors, or may include twelve thin film transistors. More specifically, it may include 4N thin film transistors.

According to FIG. 11, gate electrodes (Ga, Gb, Gc, Gd, Ge, Gf, Gg, Gh) and drain electrodes (Da, Db, Dc, Dd, De, Df, Dg, Dh) are connected to each other, and a high-potential power supply voltage GVDD_o is applied.

According to an example embodiment of the present disclosure, the eight transistors (T41a, T41b, T41c, T41d, T41e, T41f, T41g, T41h) illustrated in FIG. 11 may correspond to the first upper thin film transistor (11), the second upper thin film transistor (12), the third upper thin film transistor (13), the fourth upper thin film transistor (14), the first lower thin film transistor (21), the second lower thin film transistor (22), the third lower thin film transistor (23), and the fourth lower thin film transistor (24) illustrated in FIGS. 4 to 6.

According to various example embodiments of the present disclosure, the following advantageous effects may be obtained.

A thin film transistor unit according to an example embodiment of the present disclosure can disperse the current path by disposing gate electrodes in parallel at the upper and lower ends.

A thin film transistor unit according to an example embodiment of the present disclosure can reduce the risk of heat generation by disposing gate electrodes in parallel at the upper and lower ends.

A thin film transistor unit according to an example embodiment of the present disclosure can secure a process margin by reducing the width of the channel while maintaining the channel length by disposing the gate electrodes in parallel at the upper and lower ends.

In addition to the effects mentioned above, other features and advantages of the present disclosure are described above or may be clearly understood by those skilled in the art to which the present disclosure pertains from such description and explanation.

It will be apparent to those skilled in the art that the present disclosure described above is not limited by the above-described example embodiments and the accompanying drawings and that various substitutions, modifications and variations can be made in the present disclosure without departing from the spirit or scope of the disclosures. Consequently, the protected scope of the present disclosure may be defined by the accompanying claims and their equivalents, and it is intended that all variations or modifications derived from the meaning, scope, and equivalent concept of the claims fall within the scope of the present disclosure.

What is claimed is:

1. A thin film transistor unit, comprising:
a base substrate;
a first lower thin film transistor and a second lower thin film transistor disposed on the base substrate and connected in parallel to each other; and
a first upper thin film transistor and a second upper thin film transistor disposed on the first lower thin film transistor and the second lower thin film transistor and connected in parallel to each other,
wherein the first upper thin film transistor includes a first upper active layer and a first upper gate electrode disposed on the first upper active layer,
wherein the second upper thin film transistor includes a second upper active layer and a second upper gate electrode disposed on the second upper active layer,
wherein the first upper gate electrode and the second upper gate electrode are electrically connected, with a first upper drain electrode being interposed therebetween,
wherein the first lower thin film transistor includes a first lower gate electrode and a first lower active layer disposed on the first lower gate electrode,
wherein the second lower thin film transistor includes a second lower gate electrode and a second lower active layer disposed on the second lower gate electrode, and
wherein the first lower gate electrode and the second lower gate electrode are electrically connected, with a first lower drain electrode being interposed therebetween.

2. The thin film transistor unit of claim 1, wherein the first upper gate electrode, the second upper gate electrode and the first upper drain electrode are formed integrally, and
wherein the first lower gate electrode, the second lower gate electrode and the first lower drain electrode are formed integrally.

3. The thin film transistor unit of claim 1, wherein the first upper active layer of the first upper thin film transistor and the second upper active layer of the second upper thin film transistor are spaced apart from each other with a first connecting portion therebetween, and
wherein the first lower active layer of the first lower thin film transistor and the second lower active layer of the second lower thin film transistor are spaced apart from each other with a second connecting portion therebetween.

4. The thin film transistor unit of claim 3, wherein the first upper active layer of the first upper thin film transistor and the second upper active layer of the second upper thin film transistor are formed integrally with the first connecting portion, and
wherein the first lower active layer of the first lower thin film transistor and the second lower active layer of the second lower thin film transistor are formed integrally with the second connecting portion.

5. The thin film transistor unit of claim 1, wherein the first upper gate electrode overlaps the first lower gate electrode, and the second upper gate electrode overlaps the second lower gate electrode in a plan view.

6. The thin film transistor unit of claim 1, wherein the first upper active layer of the first upper thin film transistor overlaps the first lower active layer of the first lower thin film transistor, and the second upper active layer of the second upper thin film transistor overlaps the second lower active layer of the second lower thin film transistor in a plan view.

7. The thin film transistor unit of claim 3, wherein the first connecting portion is in contact with the first upper drain electrode, and the second connecting portion is in contact with the first lower drain electrode.

8. The thin film transistor unit of claim 1, further including a first buffer layer disposed between the first lower thin film transistor and the first upper thin film transistor, and disposed between the second lower thin film transistor and the second upper thin film transistor.

9. The thin film transistor unit of claim 8, wherein the first upper active layer of the first upper thin film transistor is disposed between the first buffer layer and the first upper gate electrode, and the second upper active layer of the second upper thin film transistor is disposed between the first buffer layer and the second upper gate electrode.

10. The thin film transistor unit of claim 8, wherein the first lower active layer of the first lower thin film transistor is disposed between the first buffer layer and the first lower gate electrode, and the second lower active layer of the second lower thin film transistor is disposed between the first buffer layer and the second lower gate electrode.

11. The thin film transistor unit of claim 8, further including a second buffer layer disposed between the base substrate and the first buffer layer,
wherein the first buffer layer is formed by being patterned, and
wherein the second buffer layer is disposed on an entire upper surface of the base substrate.

12. The thin film transistor unit of claim 1, further includes a first source electrode and a second source electrode, which are spaced apart from each other,
wherein the first source electrode is disposed spaced apart from the first upper drain electrode with the first upper active layer of the first upper thin film transistor interposed therebetween, and is disposed spaced apart from the first lower drain electrode with the first lower active layer of the first lower thin film transistor interposed therebetween, and
wherein the second source electrode is disposed spaced apart from the first upper drain electrode with the second upper active layer of the second upper thin film transistor interposed therebetween, and is disposed spaced apart from the first lower drain electrode with the second lower active layer of the second lower thin film transistor interposed therebetween.

13. The thin film transistor unit of claim 12, wherein the first source electrode contacts the first upper active layer of the first upper thin film transistor and the first lower active layer of the first lower thin film transistor, respectively, and
wherein the second source electrode contacts the second upper active layer of the second upper thin film transistor and the second lower active layer of the second lower thin film transistor, respectively.

14. The thin film transistor unit of claim 8, wherein the first upper drain electrode and the first lower drain electrode are connected through a first contact hole formed in the first buffer layer.

15. The thin film transistor unit of claim 1, wherein the first upper thin film transistor further includes a first gate insulating film disposed between the first upper active layer and the first upper gate electrode of the first upper thin film transistor,
wherein the second upper thin film transistor further includes a second gate insulating film disposed between the second upper active layer and the second upper gate electrode of the second upper thin film transistor,
wherein the first gate insulating film and the second gate insulating film are spaced apart from each other with a second contact hole therebetween,
wherein the first lower thin film transistor further includes a third gate insulating film disposed between the first lower active layer and the first lower gate electrode of the first lower thin film transistor,
wherein the second lower thin film transistor further includes a fourth gate insulating film disposed between the second lower active layer and the second lower gate electrode of the second lower thin film transistor, and
wherein the third gate insulating film and the fourth gate insulating film are spaced apart from each other with a third contact hole therebetween.

16. The thin film transistor unit of claim 15, wherein the first upper drain electrode is formed within the second contact hole.

17. The thin film transistor unit of claim 15, wherein the second contact hole and the third contact hole are disposed to overlap each other in a plan view.

18. The thin film transistor unit of claim 1, wherein the first lower active layer of the first lower thin film transistor has a larger area than the first upper active layer of the first upper thin film transistor in a plan view.

19. The thin film transistor unit of claim 1, wherein the second lower active layer of the second lower thin film transistor has a larger area than the second upper active layer of the second upper thin film transistor in a plan view.

20. The thin film transistor unit of claim 1, wherein the first upper thin film transistor and the second upper thin film transistor are disposed along a first direction,
wherein the first lower thin film transistor and the second lower thin film transistor are disposed along the first direction, and
when a direction intersecting the first direction is referred to as a second direction, wherein the thin film transistor unit further includes a third upper thin film transistor disposed along the second direction with the first upper thin film transistor, a fourth upper thin film transistor disposed along the second direction with the second upper thin film transistor, a third lower thin film transistor disposed along the second direction with the first lower thin film transistor, and a fourth lower thin film transistor disposed along the second direction with the second lower thin film transistor, and
wherein the third upper thin film transistor and the fourth upper thin film transistor are connected in parallel to each other, and the third lower thin film transistor and the fourth lower thin film transistor are connected in parallel to each other.

21. The thin film transistor unit of claim 20, wherein the third upper thin film transistor includes a third upper active layer and a third upper gate electrode disposed on the third upper active layer,
wherein the fourth upper thin film transistor includes a fourth upper active layer and a fourth upper gate electrode disposed on the fourth upper active layer,
wherein the third upper gate electrode and the fourth upper gate electrode are electrically connected, with a second upper drain electrode being interposed therebetween,
wherein the third lower thin film transistor includes a third lower gate electrode and a third lower active layer disposed on the third lower gate electrode,
wherein the fourth lower thin film transistor includes a fourth lower gate electrode and a fourth lower active layer disposed on the fourth lower gate electrode, and
wherein the third lower gate electrode and the fourth lower gate electrode are electrically connected, with a second lower drain electrode being interposed therebetween.

22. The thin film transistor unit of claim 21, wherein the first upper drain electrode and the second upper drain electrode are electrically connected with an upper bridge electrode therebetween,
wherein the first lower drain electrode and the second lower drain electrode are electrically connected with a lower bridge electrode therebetween, and
wherein the upper bridge electrode and the lower bridge electrode overlaps in a plan view.

23. A display apparatus comprising the thin film transistor unit of claim 1.
